(19) United States
(12) Patent Application Publication
(10) Pub. No.: US 2020/0059207 A1
(43) Pub. Date: Feb. 20, 2020

(54) Reconfigurable LNA design for FR front end

(71) Applicant: Qualcomm Incorporated, San Diego, CA (US)

(72) Inventors: Serkan SAYILIR, San Jose, CA (US); Wei CHENG, San Diego, CA (US); Francesco GATTA, San Diego, CA (US)

(21) Appl. No.: 15/999,046

(22) Filed: Aug. 17, 2018

(51) Int. Cl. H03F 3/195; H03F 1/56; H04B 1/50; H01Q 21/00; H01Q 23/00; H05K 1/02

(52) U.S. Cl. CPC H03F 3/195; H03F 1/565; H04B 1/50; H03F 2200/451; H01Q 23/00; H05K 1/0237; H03F 2200/294; H01Q 21/0025

(57) ABSTRACT

The present disclosure provides a reconfigurable low noise amplifier (LNA) circuit. This reconfigurable LNA circuit can be used for connecting multiple receive signal paths to a particular LNA in one configuration as well as used for connecting a single receive signal path to a particular LNA in another configuration. In the single receive signal path configuration, the single receive signal path is not degraded by the parasitics of a particular set of switches used for the multiple receive signal paths configuration.

### FIELD

The present disclosure relates generally to wireless communications and more particularly to low noise amplifier (LNA) integrated circuit configurations.

### BACKGROUND

A wireless device (e.g., a cellular phone or a smartphone) in a wireless communication system may transmit and receive data for two-way communication. The wireless device may include a transmitter for data transmission and a receiver for data reception. For data transmission, the transmitter may modulate a radio frequency (RF) carrier signal with data to obtain a modulated RF signal, amplify the modulated RF signal to obtain an amplified RF signal having the proper output power level, and transmit the amplified RF signal via an antenna to a base station. For data reception, the receiver may obtain a received RF signal via the antenna and may amplify and process the received RF signal to recover data sent by the base station.

The transmitter and the receiver may have some and/or all portions integrated onto a single integrated circuit. For example, portions of the receiver may be integrated onto one such integrated circuit that includes at least one low noise amplifier (LNA). The LNA amplifies a received RF signal. Some wireless devices may need to support multiple frequency bands. At least some of the multiple bands may be received using different receive signal paths. At least some of these multiple receive signal paths may be amplified by a single LNA. Integrated circuits for LNAs that are able to support different receive signal path configurations in different wireless devices are desirable.

### SUMMARY

This Summary is provided to introduce in a simplified form a selection of concepts that are further described below in the Detailed Description. This Summary is not intended to identify key features or essential features of the claimed subject matter, nor is it intended to limit the scope of the claimed subject matter.

Aspects of the disclosure are directed to reconfigurable low noise amplifier that can be used for connecting multiple receive signal paths to a particular LNA in one configuration as well as used for connecting a single receive signal path to the particular LNA in another configuration. In the single receive signal path configuration, performance of the single receive signal path is not degraded by the parasitics of switches used for the multiple receive signal path configuration.

In one example an apparatus comprises an integrated circuit. The integrated circuit comprises a first port connected to a first switch, a second port connected to a second switch, a third port connected to both the first switch and the second switch, a fourth port, a fifth port, wherein the fifth port is connected to a low noise amplifier (LNA), and a bypass path that is connected to the fourth port and that bypasses the low noise amplifier.

In another example, an apparatus comprises an integrated circuit. The integrated circuit comprises means for connecting a first port to a first switch, means for connecting a second port to a second switch, means for connecting a third port to both the first switch and the second switch, and means for connecting a fourth port to a bypass path, wherein the bypass path bypasses a low noise amplifier (LNA), and means for connecting a fifth port to the LNA.

In another example, a method of amplifying a signal includes receiving the signal at a fourth port of an integrated circuit that includes a first port connected to a first switch, a second port connected to a second switch, a third port connected to both the first switch and the second switch, the fourth port, a fifth port connected to the fourth port and a low noise amplifier (LNA), and a bypass path that is connected to the fourth port and that bypasses the low noise amplifier. The method further includes amplifying the signal using the low noise amplifier.

### BRIEF DESCRIPTION OF THE DRAWINGS

FIG. 1 is a diagram of wireless device communication in a wireless system according to an aspect of the present disclosure.

FIG. 2 is a functional block diagram of the wireless device of FIG. 1 according to an aspect of the present disclosure.

FIG. 3 is a functional block diagram of an example of a wireless device having a single receive signal path input to a single LNA.

FIG. 4 is a functional block diagram of an example of a wireless device having multiple receive signal paths input to a single LNA.

FIG. 5 is a schematic diagram of an example of an LNA integrated circuit capable of routing multiple receive signal paths to one or more LNAs.

FIGS. 6A and 6B are schematic diagrams of another example of an LNA integrated circuit capable of routing multiple receive signal paths to a single LNA.

FIGS. 7A, 7B, and 7C are a schematic diagrams of another example of an LNA integrated circuit capable of routing multiple receive signal paths to a one or more LNAs.

FIGS. 8A and 8B are schematic diagrams of another example of an LNA integrated circuit capable of routing multiple receive signal paths to a single LNA.

FIG. 9 is a flowchart of an example of a method of amplifying a signal.

### DETAILED DESCRIPTION

The detailed description set forth below in connection with the appended drawings is intended as a description of exemplary implementations and is not intended to represent the only implementations in which the invention may be practiced. The term “exemplary” used throughout this description means “serving as an example, instance, or illustration,” and should not necessarily be construed as preferred or advantageous over other exemplary implementations. The detailed description includes specific details for the purpose of providing a thorough understanding of the exemplary implementations. In some instances, some devices are shown in block diagram form. Drawing elements that are common among the following figures may be identified using the same reference numerals.

Some wireless device models may need to support multiple frequency bands. At least some of the multiple bands may be received using different receive signal paths. In at least one aspect, a signal path may correspond to one or more conductive elements/traces and/or components along which or through a signal may be propagated and processed or conditioned. At least some of these multiple receive signal paths may be amplified by a single LNA. Each of the multiple receive signal paths amplified by a single LNA may be routed through a set of switches, one switch for each of the multiple receive signal paths. The switches are typically integrated onto the same integrated circuit as the LNA. The switches include parasitic capacitances and resistances which may affect the noise figure and linearity of a particular receive signal path.

A different model of a wireless device may not need to route multiple receive signal paths to a particular LNA. For example, a particular LNA may not need to support multiple bands. In this case, only a single receive signal path needs to be routed to a particular LNA. There is no need for a switch or a set of switches in this case because the single receive signal path can be directly connected to the LNA.

One option for a model of a wireless device that does not need to route multiple receive signal paths to a particular LNA is to design a new integrated circuit without a set of switches. The new integrated circuit design would require additional design and test costs as well as time. By having different parts for different device models, there would be reduced economies of scale because the different parts would incur their own design, manufacturing, test, and customer support costs. For example, each design would need its own tape-out, mask set, production run, yield optimization, characterization, testing, and validation.

Another option is to use the integrated circuit designed to connect multiple receive signal paths to a particular LNA for the device model that connects a single receive signal path to a particular LNA. The single receive signal path could be routed through one of the switches for the multiple receive signal paths. Alternatively, the single receive signal path could be connected to the integrated circuit just after the set of switches for the multiple receive signal paths. In either case, the single receive signal path would see some of the parasitic resistances and/or parasitic capacitances of the switches. These parasitic resistance and/or parasitic capacitances may degrade the performance of the receiver.

Aspects of the present disclosure provide for a reconfigurable LNA integrated circuit that can be used for connecting multiple receive signal paths to a particular LNA in one configuration as well as used for connecting a single receive signal path to the particular LNA in another configuration. In an aspect, an LNA integrated circuit is provided where a single receive signal path is not degraded by the parasitics of a particular set of switches used for the multiple receive signal paths configuration. This LNA integrated circuit can be provided in multiple different device models avoiding the need for separate designs that would each incur its own tape-out, mask set, production run, yield optimization, characterization, testing, and validation.

More particularly, certain aspects of the disclosure provide for an LNA integrated circuit with a port that is either used for connecting multiple receive signal paths to a particular LNA in one configuration or used for connecting a single receive signal path to the particular LNA in another configuration. In an aspect, the connections to the port are external to the LNA integrated circuit. Moreover, in an aspect, the port is connected to a bypass path where a signal at the port can go through either the bypass path or the particular LNA (or both).

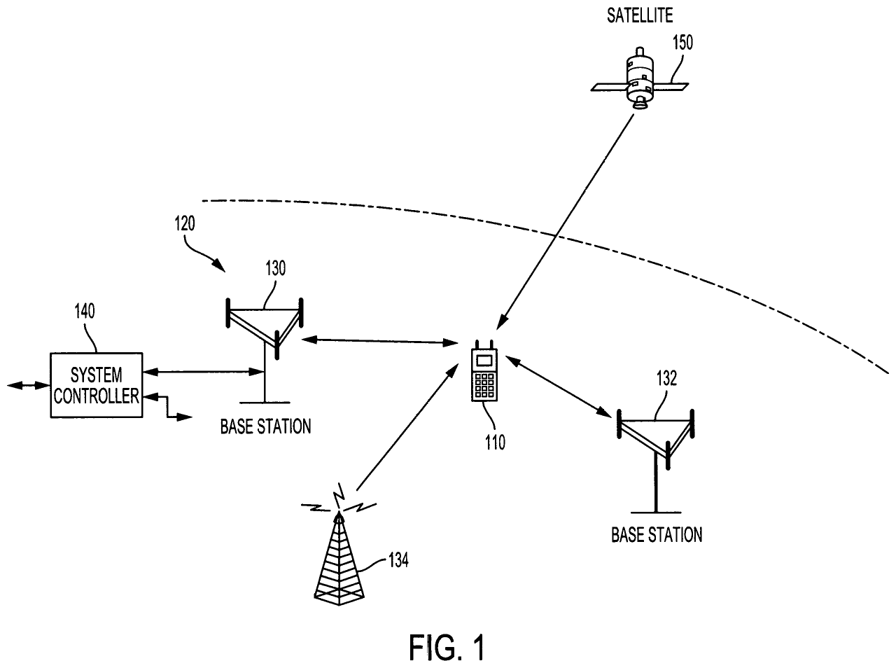

FIG. 1 shows a wireless device 110 communicating with a wireless communication system 120, in accordance with some exemplary embodiments. Wireless communication system 120 may be a 3rd Generation Partnership Program (3GPP) Long Term Evolution (LTE) system, a Code Division Multiple Access (CDMA) system, a Global System for Mobile Communications (GSM) system, a wireless local area network (WLAN) system, or some other wireless system. A CDMA system may implement Wideband CDMA (WCDMA), CDMA 1X, Evolution-Data Optimized (EVDO), Time Division Synchronous CDMA (TD-SCDMA), or some other version of CDMA. For simplicity, FIG. 1 shows wireless communication system 120 including two base stations 130 and 132 and one system controller 140. In general, a wireless system may include any number of base stations and any set of network entities.

Wireless device 110 may also be referred to as a user equipment (UE), a mobile station, wireless communications device, a terminal, an access terminal, a subscriber unit, a station, etc. Wireless device 110 may be a cellular phone, a smartphone, a tablet, a wireless modem, a personal digital assistant (PDA), a handheld device, a laptop computer, vehicle unit, a smartbook, a netbook, a cordless phone, a wireless local loop (WLL) station, a Bluetooth device, etc. Wireless device 110 may communicate with wireless communication system 120. Wireless device 110 may also receive signals from broadcast stations (e.g., a broadcast station 134), signals from satellites (e.g., a satellite 150) in one or more global navigation satellite systems (GNSS), etc. Wireless device 110 may support one or more radio technologies for wireless communication such as LTE, WCDMA, CDMA 1X, EVDO, TD-SCDMA, GSM, 802.11, etc.

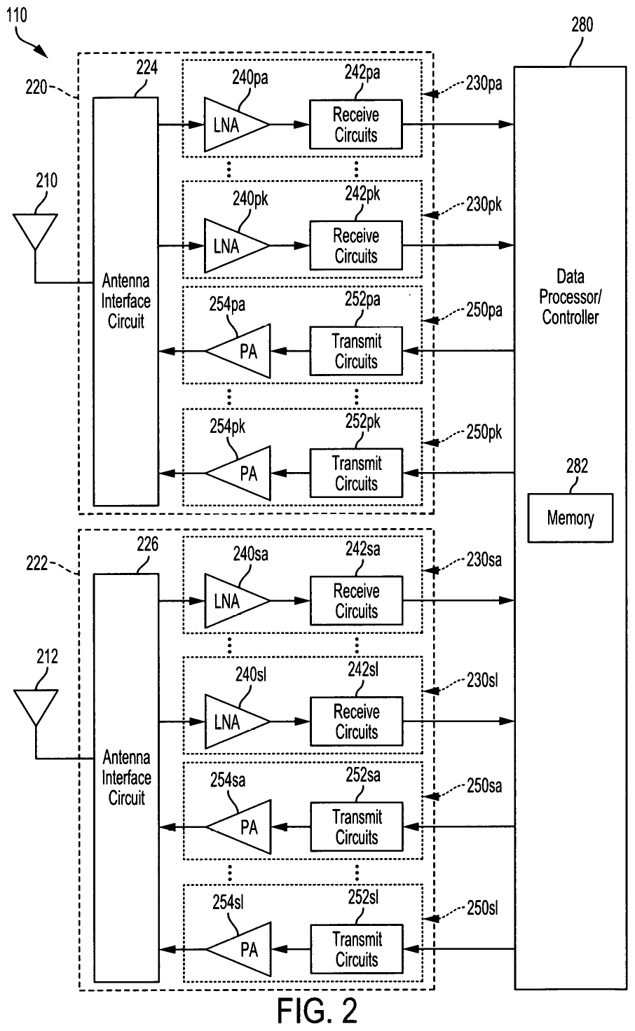

FIG. 2 shows a block diagram of an exemplary design of wireless device 110 in FIG. 1. In this exemplary design, wireless device 110 includes a primary transceiver 220 coupled to a primary antenna 210, a secondary transceiver 222 coupled to a secondary antenna 212, and a data processor/controller 280. In certain aspects, the secondary transceiver 222 may be optional and the wireless device 110 includes just the primary transceiver 220. In certain aspects, the secondary transceiver 222 is coupled to the primary antenna 210 and the secondary antenna 212 is optional or connected to yet another transceiver (not shown).

Primary transceiver 220 includes a number (K) of receivers 230pa to 230pk and a number (K) of transmitters 250pa to 250pk to support multiple frequency bands, multiple radio technologies, carrier aggregation, etc. Secondary transceiver 222 includes a number (L) of receivers 230sa to 230s1 and a number (L) of transmitters 250sa to 250s1 to support multiple frequency bands, multiple radio technologies, carrier aggregation, receive diversity, multiple-input multiple-output (MIMO) transmission from multiple transmit antennas to multiple receive antennas, etc.

In the exemplary design shown in FIG. 2, each receiver 230 includes a low noise amplifier (LNA) 240 and receive circuits 242. For data reception, primary antenna 210 receives signals from base stations and/or other transmitter stations and provides a received radio frequency (RF) signal, which is routed through an antenna interface circuit 224 and presented as an input RF signal to a selected receiver. Antenna interface circuit 224 may include switches, duplexers, transmit filters, receive filters, matching circuits, etc. The description below assumes that receiver 230pa is the selected receiver. Within receiver 230pa, an LNA 240pa amplifies the input RF signal and provides an output RF signal. Receive circuits 242pa downconvert the output RF signal from RF to baseband, amplify and filter the downconverted signal, and provide an analog input signal to data processor/controller 280. Receive circuits 242pa may include mixers, filters, amplifiers, matching circuits, an oscillator, a local oscillator (LO) generator, a phase locked loop (PLL), etc. Each remaining receiver 230 in transceivers 220 and 222 may operate in similar manner as receiver 230pa.

In the exemplary design shown in FIG. 2, each transmitter 250 includes transmit circuits 252 and a power amplifier (PA) 254. For data transmission, data processor/controller 280 processes (e.g., encodes and modulates) data to be transmitted and provides an analog output signal to a selected transmitter. The description below assumes that transmitter 250pa is the selected transmitter. Within transmitter 250pa, transmit circuits 252pa amplify, filter, and upconvert the analog output signal from baseband to RF and provide a modulated RF signal. Transmit circuits 252pa may include amplifiers, filters, mixers, matching circuits, an oscillator, an LO generator, a PLL, etc. A PA 254pa receives and amplifies the modulated RF signal and provides a transmit RF signal having the proper output power level. The transmit RF signal is routed through antenna interface circuit 224 and transmitted via primary antenna 210. Each remaining transmitter 250 in transceivers 220 and 222 may operate in similar manner as transmitter 250pa.

Each receiver 230 and transmitter 250 may also include other circuits not shown in FIG. 2, such as filters, matching circuits, etc. All or a portion of transceivers 220 and 222 may be implemented on one or more analog integrated circuits (ICs), RF ICs (RFICs), mixed-signal ICs, etc. For example, LNAs 240 and receive circuits 242 within transceivers 220 and 222 may be implemented on multiple IC chips, as described below. The circuits in transceivers 220 and 222 may also be implemented in other manners.

Data processor/controller 280 may perform various functions for wireless device 110.

For example, data processor/controller 280 may perform processing for data being received via receivers 230 and data being transmitted via transmitters 250. Data processor/controller 280 may control the operation of the various circuits within transceivers 220 and 222. A memory 282 may store program codes and data for data processor/controller 280. For example, the data processor/controller 280 is configured to access the memory 282 and execute one or more instructions stored on the memory for performing one or more operations associated with wireless communications such as for routing signals, activating signal paths, and/or processing data. Data processor/controller 280 may be implemented on one or more application specific integrated circuits (ASICs) and/or other ICs.

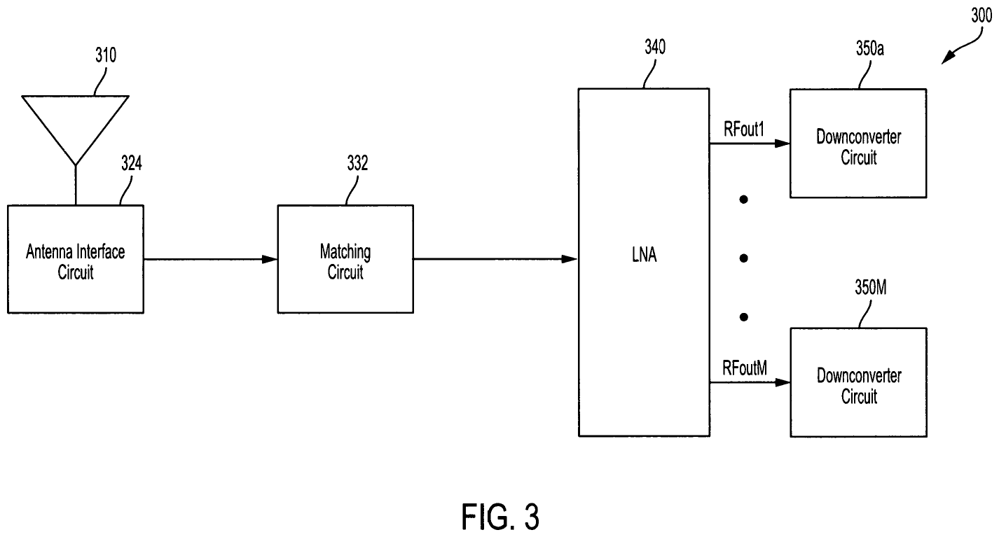

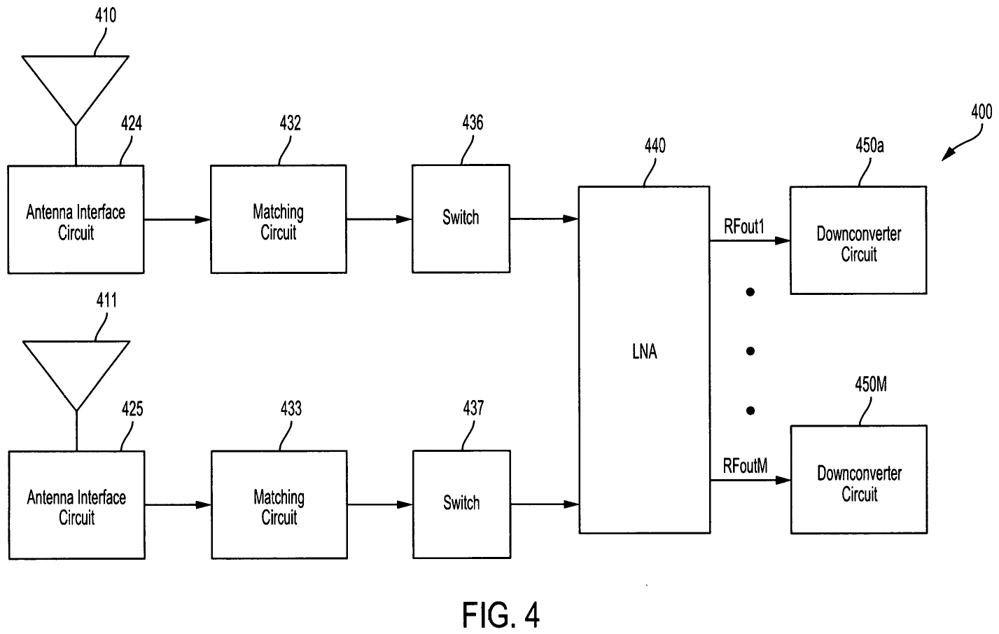

As noted above, different device models or different transceiver circuits within a single device may have different numbers of receive signal paths connected to a particular LNA. FIGS. 3 and 4 illustrate examples of two different transceiver configurations.

FIG. 3 is a functional block diagram of an example of a receiver 300 of a wireless device (e.g., the device 110) having a single receive signal path input to a low noise amplifier (LNA) integrated circuit 340. The LNA integrated circuit 340 may be used for one or more LNAs 240 shown in FIG. 2. The LNA integrated circuit 340 includes a single input and multiple (M) outputs, where M>=1.

At the receiver 300, an antenna 310 is configured to receive downlink signals comprising one or more transmissions sent on one or more carriers. The antenna 310 provides the received RF signal to an antenna interface circuit 324. The antenna interface circuit 324 is configured to filter and route the received RF signal and provides a receiver input signal, RXin. An input matching circuit 332 is configured to receive the RXin signal and provide an input RF signal, RFin, to the LNA integrated circuit 340. A matching circuit 332 may perform impedance and/or power matching between the LNA integrated circuit 340 and either the antenna interface circuit 324 or the antenna 310 for a band of interest.

The LNA integrated circuit 340 is configured to receive and amplify the input RFin signal and provide an output RF signal via one or more LNA outputs for up to M output RF signals, RFout1 to RFoutM (e.g., multiple outputs may be useful for carrier aggregation scenarios where a transmission is received on different bands). M downconverter circuits 350a to 350M are coupled to the M LNA outputs. Each downconverter circuit 350, when enabled, is configured to downconvert an associated output RF signal such that one or more transmissions on one or more carriers of interest are downconverted from RF to baseband.

The LNA integrated circuit 340 may operate in a single-output mode or a multi-output mode at any given moment. In the single-output mode, the LNA integrated circuit 340 operates in a 1-input to 1-output (1×1) configuration, and receives one input RF signal comprising one or more transmissions on one set of carriers, and provides one output RF signal to one downconverter circuit (e.g., downconverter circuit 350a). The single-output mode may be used to receive a transmission sent on a single carrier without carrier aggregation. The single-output mode may also be used to receive transmissions sent on multiple carriers (e.g., contiguous carriers) with carrier aggregation. In this case, the transmissions on all carriers may be downconverted with a single local oscillator (LO) signal at a single frequency.

In the multi-output mode, the LNA integrated circuit 340 operates in a 1×M configuration, receives one input RF signal comprising multiple transmissions on M sets of carriers, and provides M output RF signals to M downconverter circuits 350a and 350M (e.g., one output RF signal for each set of carriers, where M>1). Each set of carriers may include one or more carriers in a single band (e.g., intra-band CA) or across multiple bands (e.g., inter-band CA).

FIG. 4 is a functional block diagram of an example of a receiver 400 of a wireless device 110 having multiple receive signal paths input to a single LNA integrated circuit 440. The LNA integrated circuit 440 may be used for one or more LNAs 240 shown in FIG. 2. The LNA integrated circuit 440 includes multiple inputs and multiple (M) outputs, where M>=1.

The receiver 400 includes two different receive signal paths each connected to their own respective first antenna 410 and second antenna 411. It should be appreciated that in some implementations, the two receive signal paths may share a single antenna such as first antenna 410 (e.g., see the description with respect to the multiple receive signal paths of FIG. 2 sharing antenna 210). The first antenna 410 is connected to a first antenna interface circuit 424 configured as described above with reference to FIGS. 2 and 3. The second antenna 411 is connected to a second antenna interface circuit 425 configured as described above with reference to FIGS. 2 and 3. In some implementations where a single antenna is shared by the two receive signal paths, there may be only a single antenna interface circuit 424 similar to the antenna interface circuit 224 described above with reference to FIG. 2. Each of the first and second receive signal paths further includes a corresponding first matching circuit 432 and second matching circuit 433 configured as described above with reference to FIG. 3.

The two receive signal paths share a single LNA integrated circuit 440. The LNA integrated circuit 440 has two inputs (more are also possible). In the first receive signal path, a first switch 436 is connected between the first matching circuit 432 and the LNA integrated circuit 440. In the second receive signal path, a second switch 437 is connected between the second matching circuit 433 and the LNA integrated circuit 440. The first switch 436 is configured to selectively route (e.g., based on a control signal) a signal received through the first receive signal path to the LNA integrated circuit 440 so that the signal is amplified by the LNA integrated circuit 440. Likewise, the second switch 437 is configured to selectively route a signal received through the second receive signal path to the LNA integrated circuit 440 so that the signal is amplified by the LNA integrated circuit 440. The first and second switches 436 and 437 provide for allowing the LNA integrated circuit 440 to selectively receive either a signal received through the first receive signal path or a signal received through the second receive signal path, but not both, during some time period. However, certain implementations may allow for both the first and second receive signal path to be connected to the LNA integrated circuit 440 simultaneously. In certain implementations, the first and second switches 436 and 437 are part of the LNA integrated circuit 440.

The LNA integrated circuit 440 is configured to receive and amplify either the input received through the first receive signal path or the input received through the second receive signal path or potentially both (based on the state/configuration of first switch 436 and the second switch 437) and provide an output RF signal via one or more LNA outputs for up to M output RF signals, RFout1 to RFoutM. M downconverter circuits 450a to 450M are coupled to the M LNA outputs. Each downconverter circuit 450, when enabled, is configured to downconvert an associated output RF signal such that one or more transmissions on one or more carriers of interest are downconverted from RF to baseband.

As described above with reference to FIG. 3, the LNA integrated circuit 440 may operate in a single-output mode or a multi-output mode at any given moment. In the single-output mode, the LNA integrated circuit 440 operates in a 1-input to 1-output (1×1) configuration, and receives one input RF signal (either from first receive signal path or second receive signal path) comprising one or more transmissions on one set of carriers, and provides one output RF signal to one downconverter circuit (e.g., downconverter circuit 450a). The single-output mode may be used to receive a transmission sent on a single carrier without carrier aggregation. The single-output mode may also be used to receive transmissions sent on multiple carriers (e.g., contiguous carriers) with carrier aggregation. In this case, the transmissions on all carriers may be downconverted with a single local oscillator (LO) signal at a single frequency. In the multi-output mode, the LNA integrated circuit 440 operates in a N×M configuration, receives one or more input RF signals comprising multiple transmissions on M sets of carriers (e.g., either via first and second receive signal paths), and provides M output RF signals to M downconverter circuits, one output RF signal for each set of carriers, where M>1. Each set of carriers may include one or more carriers in a single band (e.g., intra-band CA) or across multiple bands (e.g., inter-band CA).

In some implementations both receive signal paths may be active simultaneously (e.g., signals from both of the first and second receive signal paths may be amplified by the INA integrated circuit 440 simultaneously where each of the first and second switches 436 and 437 allow signals to be input into the LNA integrated circuit 440).

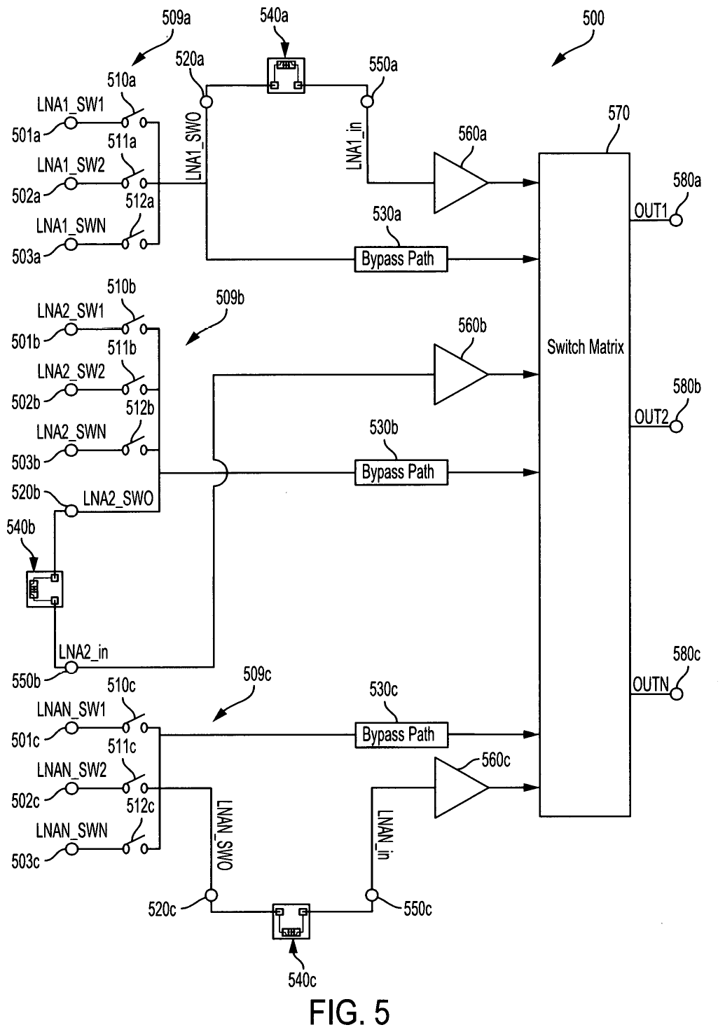

FIG. 5 is a schematic diagram of an example of an LNA integrated circuit 500 capable of routing multiple receive signal paths to one or more LNAs. The LNA integrated circuit 500 may correspond to the LNA integrated circuit 440 described with reference to FIG. 4. The LNA integrated circuit 500 is configured to support multiple receive signal paths shared amongst multiple LNAs 560a, 560b, and 560c in different configurations. The LNA integrated circuit 500 includes three LNA circuits including a first LNA 560a, a second LNA 560b, and a third LNA 560c. While FIG. 5 illustrates three LNAs 560a, 560b, and 560c, fewer or more LNAs may be provided in other implementations.

Each of the LNAs 560a, 560b, and 560c is connected to respective sets of selectable receive signal paths. The first LNA 560a is connected to a first set of receive signal paths 509a including three selectable receive signal paths. Each receive signal path in the first set of signal paths 509a includes a respective input port 501a, 502a, and 503a. Each input port 501a, 502a, and 503a may include or be configured as a chip pad (die pad or bump) to allow respective connections to be applied to the input ports 501a, 502a, and 503a as desired. Each input port 501a, 502a, and 503a is connected to a respective switch 510a, 511a, and 512a. Each of the switches 510a, 511a, 512a is connected between the corresponding input port 501a, 502a, and 503a and the first LNA 560a. A reactive component 540a such as an inductor (e.g., or some reactive network or matching network (e.g., for input matching) or isolation component) may be connected between the first set of receive signal paths 509a and the first LNA 560a. Particularly, the reactive component 540a is connected to a common port 520a that is connected to the first set of receive signal paths 509a. The common port 520a is connected to each of the switches 510a, 511a, and 512a. The reactive component 540a is connected to an LNA input port 550a that is connected to the first LNA 560a. The reactive component 540a may be external to the LNA integrated circuit 500. For example, the common port 520a and the LNA input port 550a may include or be configured as chip pads that allow a the reactive component 540a to be connected to each of the common port 520a and the LNA input port 550a depending on the characteristics of signals that will be applied to the input ports 501a, 502a, and 503.

In addition to being connected to the first LNA 560a, the first set of receive signal paths 509a is connected to a first bypass path 530a that bypasses the first LNA 560a. The first bypass path 530a may be used in various scenarios where amplification by the first LNA 560a of a particular signal along a selected receive signal path is unnecessary or undesirable. The output of the first LNA 560a and the output of the first bypass path 530a are connected to a switch matrix 570 (or other switching network) that is configured to output, at a first output port 580a, a desired signal from either the first LNA 560a or the first bypass path 530a. In an aspect, any signal at the common port 520a is routed through both the LNA 560a and the bypass path 530a. The switch matrix 570 is then configured to select which receive signal path is output at the first output port 580a. In another aspect, a switch (not shown) may be included in the bypass path 530a to allow for selectively enabling or disabling the bypass path 530a.

It should be appreciated that the first set of receive signal paths 509a or any other set of receive signal paths described herein may include more or fewer paths than the number shown (e.g., 2 or more).

In a similar configuration to the first LNA 560a, the second LNA 560b is connected to a second set of receive signal paths 509b including three selectable receive signal paths. Each receive signal path includes a respective input port 501b, 502b, and 503b. Each input port 501b, 502b, and 503b is connected to a respective switch 510b, 511b, and 512b. Each of the switches 510b, 511b, 512b is connected between the corresponding input port 501b, 502b, and 503b and the second LNA 560b. A reactive component 540b such as an inductor (e.g., or some reactive network or matching network or isolation component) may be connected between the second set of receive signal paths 509b and the second LNA 560b. The reactive component 540b is connected to a common port 520b that is connected to the second set of receive signal paths 509b. More particularly, the common port 520b is connected to each of the switches 510b, 511b, and 512b. The reactive component 540b is connected to an LNA input port 550b that is connected to the second LNA 560b. The reactive component 540b may be external to the LNA integrated circuit 500.

In addition to being connected to the second LNA 560b, the second set of receive signal paths 509b is connected to a second bypass path 530b that bypasses the second LNA 560b. The second bypass path 530b may be used in various scenarios where amplification by the second LNA 560b of a particular signal along a selected receive signal path is unnecessary or undesirable. The output of the second LNA 560b and the output of the second bypass path 530b are connected to the switch matrix 570 (or other switching network) that is configured to output, at a second output port 580b, a desired signal from either the second LNA 560b or the second bypass path 530b.

In a similar configuration to the first LNA 560a, the third LNA 560c is connected to a third set of receive signal paths 509c including three selectable receive signal paths. Each receive signal path includes a respective input port 501c, 502c, and 503c. Each input port 501c, 502c, and 503c is connected to a corresponding switch 510c, 511c, and 512c. Each of the switches 510c, 511c, 512c is connected between the corresponding input port 501c, 502c, and 503c and the third LNA 560c. A reactive component 540c such as an inductor (e.g., or some reactive network or matching network or isolation component) may be connected between the third set of receive signal paths 509c and the third LNA 560c. The reactive component 540c is connected to a common port 520c that is connected to the third set of receive signal paths 509c. More particularly, the common port 520c is connected to each of the switches 510c, 511c, and 512c. The reactive component 540c is further connected to an LNA input port 550c that is connected to the third LNA 560c. The reactive component 540c may be external to the LNA integrated circuit 500.

In addition to being connected to the third LNA 560c, the third set of receive signal paths 509c is connected to a third bypass path 530c that bypasses the third LNA 560c. The third bypass path 530c may be used in various scenarios where amplification by the third LNA 560c of a particular signal along a selected receive signal path is unnecessary or undesirable. The output of the third LNA 560c and the output of the third bypass path 530c are connected to the switch matrix 570 (or other switching network) that is configured to output, at a third output port 580c, a desired signal from either the third LNA 560c or the third bypass path 530c.

Using, for example, the first set of receive signal paths 509a, signals in multiple frequency bands may be received and may be amplified by the first LNA 560a. The switches 510a, 511a, and 512a are used to route the various signals to the first LNA 560a when one or more signals are connected to the input ports 501a, 502a, and 503a. The switches 510a, 511a, and 512a include parasitic capacitances and resistances which may affect the noise figure and linearity of a particular receive signal path. As noted above, a different model of a wireless device 110 (FIG. 1) may not use multiple receive signal paths for signals being amplified by the first LNA 560a. For example, the first LNA 560a may not need to support multiple bands. In this case, only a single receive signal path needs to be routed to the first LNA 560a. If the single receive signal path is connected directly to the common port 520a, the receive signal path through either the first LNA 560a or the bypass path 530a includes parasitic capacitances and resistances of the unused switches 510a, 511a, and 512a. This may degrade performance. As such, the integrated circuit 500 of FIG. 5A may have reduced performance for particular wireless device models that use fewer bands as compared to other device models. However, designing a new LNA integrated circuit for the single receiver path case would involve its own tape-out, mask set, production run, yield optimization, characterization, testing, and validation.

As noted above, aspects of the present disclosure provide for a reconfigurable LNA integrated circuit that can be used for connecting multiple receive signal paths to a particular LNA in one configuration as well as used for connecting a single receive signal path to a particular LNA in another configuration with improved performance.

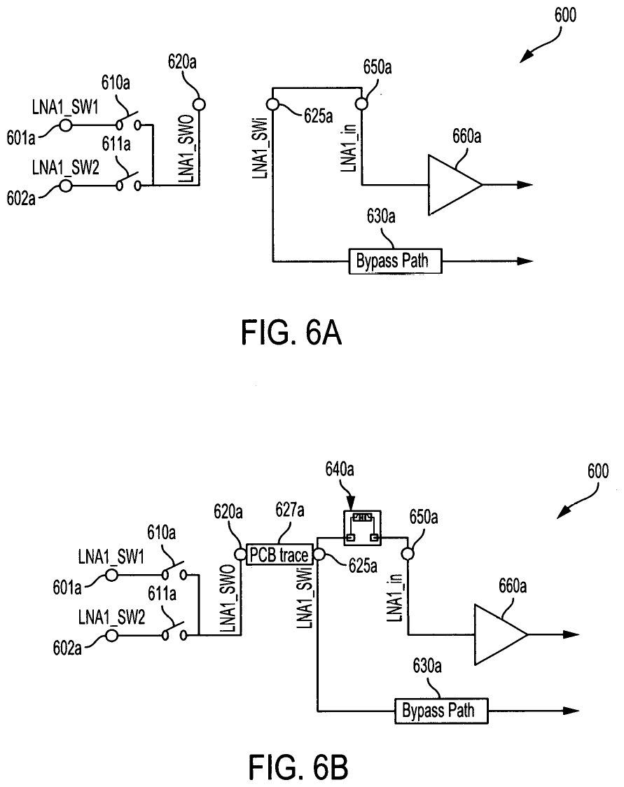

FIGS. 6A and 6B are schematic diagrams of another example of an LNA integrated circuit 600 capable of routing multiple receive signal paths to a single LNA 660a. In an aspect, the LNA integrated circuit 600 may enable a configuration that supports multiple receive signal paths as well as a configuration that supports a single receive signal path that is not degraded by the parasitics of a particular set of switches used for the multiple receive signal paths configuration. By enabling both configurations, the LNA integrated circuit 600 can support multiple device models and avoid the need for separate designs that would each incur its own tape-out, mask set, production run, yield optimization, characterization, testing, and validation.

As shown in FIG. 6A, the LNA integrated circuit 600 includes a first port 601a connected to a first switch 610a which forms a portion of first receive signal path. The LNA integrated circuit 600 includes a second port 602a connected to a second switch 611a which forms a portion of a second receive signal path. The LNA integrated circuit 600 includes a third port 620a connected to both the first switch 610a and the second switch 611a. The third port 620a is common to both the first receive signal path and the second receive signal path to allow routing signals through one or both of the receive signal paths based on the state of the switches 610a and 611a through the third port 620a. The LNA integrated circuit 600 circuit further includes a fourth port 625a. In certain implementations, the fourth port 625a and third port 620a do not include any internal electrical connection between the third port 620a and the fourth port 625a (e.g., no connection internal to the LNA integrated circuit 600). Each of the first port 601a, the second port 602a, the third port 620a, and the fourth port 625a may include or be configured as a chip pad (die pad or bump) to allow respective connections to be applied to the first port 601a, the second port 602a, the third port 620a, and the fourth port 625a as desired.

In certain aspects, the fourth port 625a is adjacent to the third port 620a. The term “adjacent” indicates, in an aspect, that the fourth port 625a is positioned relative to the third port 620a in a way that allows the third port 620a to be electrically connected to the fourth port 625a by some process separate from forming the LNA integrated circuit 600 (e.g., the connection is applied or established after the LNA integrated circuit 600 is packaged and the connection is therefore not internal to the packaged LNA integrated circuit 600). Stated another way, the fourth port 625a is positioned relative to the third port 620a to allow an external connection to be applied between the fourth port 625a and the third port 620a. The position of the fourth port 625a could be on one side, immediately next to, diagonally to, or otherwise positioned in a way to allow an electrical connection to be applied between the third port 620a and the fourth port 625a where the electrical connection is external to the LNA integrated circuit 600. This electrical connection may be either provided or omitted at a point in time when the LNA integrated circuit 600 is being integrated into a wireless device (e.g., after the LNA integrated circuit 600 has been packaged). In some aspects, there could be at least some intervening elements or some distance between the third port 620a and the fourth port 625a while still allowing an external connection to be routed between the third port 620a and the fourth port 625a.

As noted above, in an aspect, each of the third port 620a and fourth port 625a exposes or is configured as a conductive component that is external to the LNA integrated circuit 600 to allow electrical connections to be applied to third port 620a and/or the fourth port 625a.

The LNA integrated circuit 600 further includes a fifth port 650a. The fifth port 650a may be adjacent to the fourth port 625a in the same sense as that described with reference to the third port 620a and the fourth port 625a. The fifth port 650a is connected to the LNA 660a. In some implementations, the fifth port 650a may be internally electrically connected to the fourth port 625a (e.g., internally connected within the package that includes the LNA integrated circuit 600). However, in many implementations, the fifth port 650a is not internally electrically connected to the fourth port 625a but is configured as a chip pad to allow for a connection to be externally be applied between the fifth port 650a and another port such as the fourth port 625a. For example, in an aspect, the fifth port 650a exposes a conductive component external to the LNA integrated circuit 600 to allow electrical connections to be applied to the fifth port 650a (e.g., so an inductor or other matching element having particular electrical characteristics can be applied between the fourth port 625a and the fifth port 650a depending a characteristic of a signal applied at any of the first port 601a, the second port 602a or the fourth port 625a).

The LNA integrated circuit 600 further includes a bypass path 630a that is connected to the fourth port 625a and that bypasses the LNA 660a.

The LNA 660a and the bypass path 630a may be connected to a switch matrix (not shown) similar to the switch matrix 570 of FIG. 5 that may allow for controlling which signal between the output of the bypass path 630a or the output of the LNA 660a is output for further processing.

As described above, the LNA integrated circuit 600 may allow for connecting multiple receive signal paths to the LNA 660a in one configuration or be used for connecting a single receive signal path to the LNA 660a in another configuration. For example, as shown in FIG. 6B, in one configuration the LNA integrated circuit 600 includes a connection 627a between the third port 620a and the fourth port 625a. In an aspect, the connection 627a is external to the LNA integrated circuit 600. The connection 627a may be made using some form of conductive trace or other conductive connection between the third port 620a and the fourth port 625a. FIG. 6B shows the LNA integrated circuit 600 including a connection 627a, shown as printed circuit board (PCB) trace, that electrically connects the third port 620a and the fourth port 625a. While shown as a PCB trace, the connection 627a may be formed by other techniques such as for example, a multichip module (MCM) trace. As noted above, in an aspect, the third port 620a and the fourth port 625a have a conductive portion that is exposed external to the LNA integrated circuit 600 to allow for a connection 627a to be applied between the third port 620a and the fourth port 625a. All or at least one of the first port 601a, the second port 602a, the third port 620a, the fourth port 625a, and the fifth port 650a may include or be configured as a chip pad (or chip bump) that allows external connections to be applied to any or all of these ports. In another aspect, all or any number of the first port 601a, the second port 602a, the third port 620a, the fourth port 625a, and the fifth port 650a may include or is configured as a flip chip bump.

In the configuration shown in FIG. 6B, the connection 627a between the third port 620a and the fourth port 625a allows for connecting the multiple receive signal paths to the LNA 660a or through the bypass path 630a (or through both). A first receive signal path may be connected to the first port 601a and a second receive signal path may be connected to the second port 602a. The first switch 610a and the second switch 611a allow for controlling whether a receive signal path is connected to the LNA 660a and the bypass path 630a. In an aspect, this may correspond to aspects of the configuration described with reference to FIG. 4. The implementation shown in FIG. 6B may therefore allow for integration into a device model that utilizes multiple receive signal paths that share the LNA 660a.

In addition, as shown in FIG. 6B, an inductor 640a is connected between the fourth port 625a and the fifth port 650a. In an aspect the inductor 640a is external to the LNA integrated circuit 600. Being external to the LNA integrated circuit 600 may allow for different inductors (or other reactive components or networks) to be connected to allow for supporting different matching or loading for different signal bands or band combinations for signals being applied to the LNA 660a. In another aspect, the inductor 640a is internal to the LNA integrated circuit 600 in certain possible implementations. It should be noted that in certain implementations, the configuration shown in FIG. 6A may also include the inductor 640a between the fourth port 625a and the fifth port 650a.

In another configuration, in which only a single receive signal path is used, there is no connection between the third port 620a and the fourth port 625a. In this case, a first receive signal path is connected to the fourth port 625a. The first receive signal path is therefore directly connected to the LNA 660a and the bypass path 630a. Because there is no connection between the third port 620a and the fourth port 625a, the first receive signal path does not include any of the capacitances or additional resistance of the switches 610a or 611a which improves performance for this configuration. Stated another way, the first receive signal path is isolated from the switches 610a and 611a. The implementation without the connection as shown in FIG. 6A may therefore allow for integration of the LNA integrated circuit 600 into a device model that utilizes a single receive signal path in conjunction with the LNA 660a. In an aspect, this may correspond to aspects of the configuration described with reference to FIG. 3.

In another configuration, the bypass path 630a may include a switch that may allow enabling or disabling the bypass path 630a. In another configuration, the bypass path 630a may not be present. When the bypass path 630a is not present, the fifth port 650a may not be present. Also when the bypass path 630a is not present, if using a single receive signal path, the single receive signal path is connected to the fourth port 625a which is connected to the LNA 660a. Also when the bypass path 630a is not present, if multiple receive signal paths are utilized, then at least two receive signal paths are connected to the first and second ports 601a and 602a respectively and a connection 627a (e.g., trace) is added externally to connect the third port 620a and the fourth port 625a.

As described above with reference to FIG. 5, an LNA integrated circuit 500 (FIG. 5) may have multiple LNAs each associated with one or multiple receive signal paths. The techniques and configuration shown in FIGS. 6A and 6B may be applied to the configuration that includes multiple LNAs shown in FIG. 5. In this way, a single receive signal path may be directly connected to one of the LNAs without being exposed to additional switch capacitances as described with reference to FIGS. 6A and 6B while other multiple receive signal paths may be connected to another one of the LNAs.

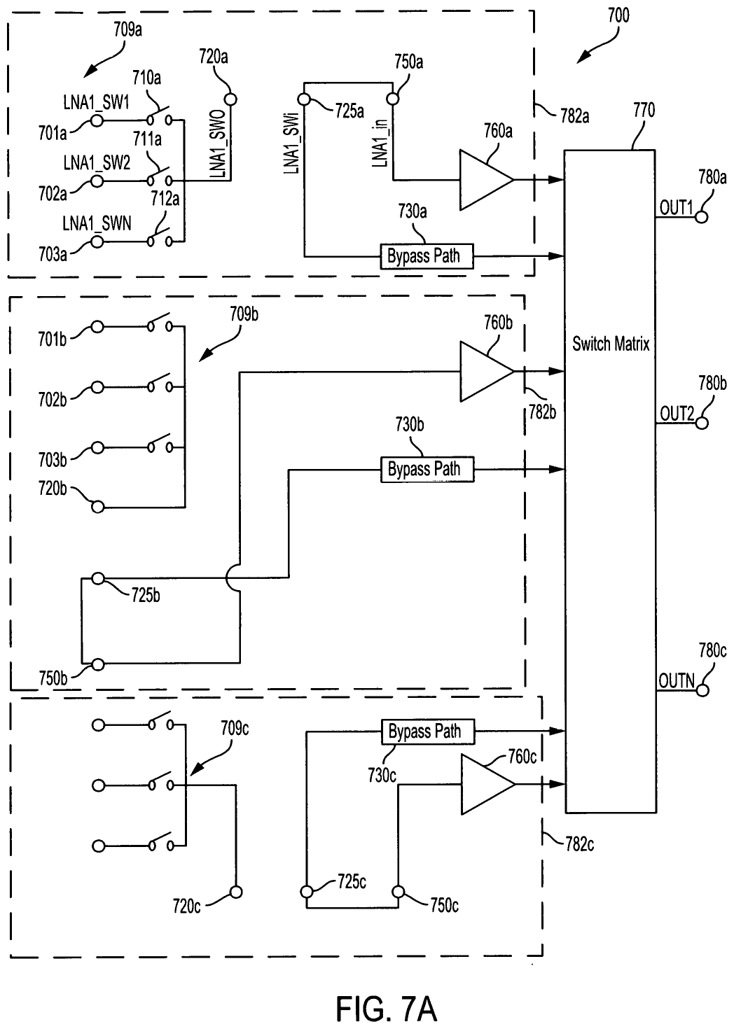

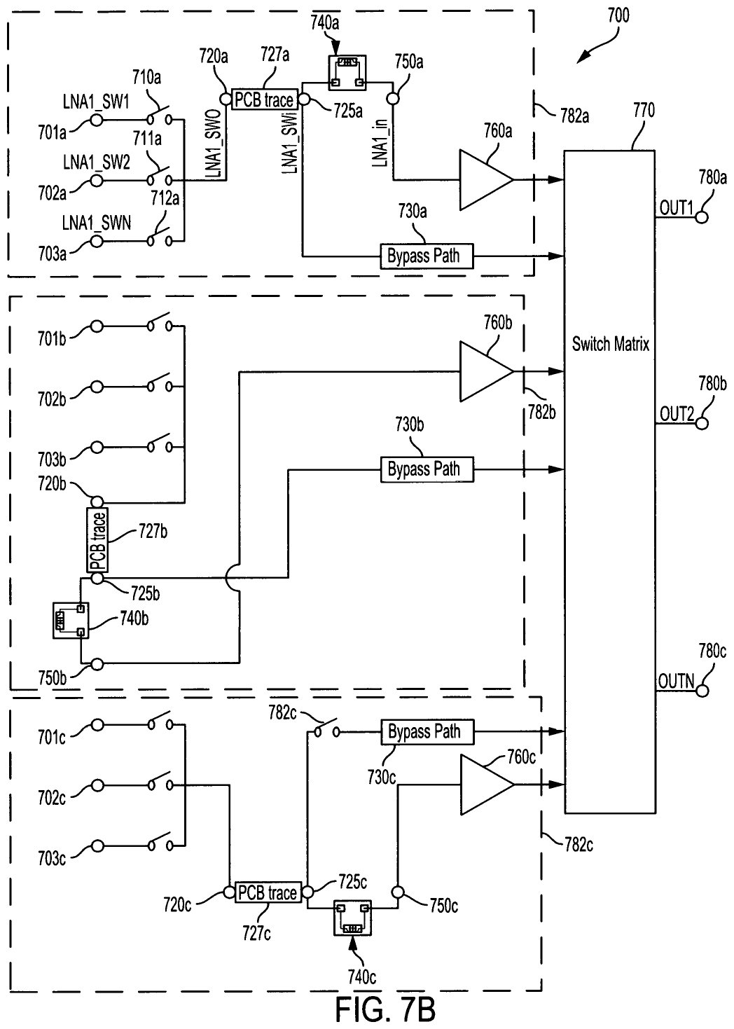

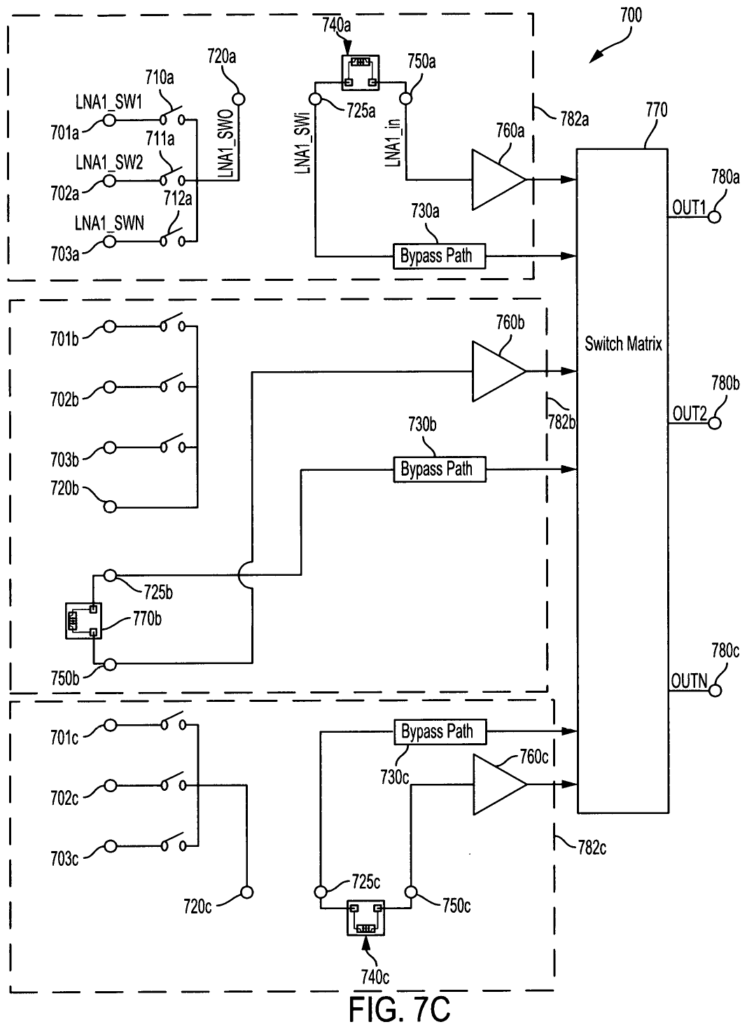

FIGS. 7A, 7B, and 7C are schematic diagrams of another example of an LNA integrated circuit 700 capable of routing multiple receive signal paths to a one or more LNAs 760a, 760b, and 760c. The LNA integrated circuit 700 includes three LNA circuits including a first LNA 760a, a second LNA 760b, and a third LNA 760c. Each of the LNAs 760a, 760b, and 760c are respectively connected to a plurality of different selectable receive signal paths. The first LNA 760a is connected to a first set of receive signal paths 709a including three (or more) selectable receive signal paths. The second LNA 760b is connected to a second set of receive signal paths 709b including three (or more) selectable receive signal paths. The third LNA 760c is connected to a third set of receive signal paths 709c including three (or more) selectable receive signal paths.

The LNA integrated circuit 700 includes a first LNA circuit portion 782a that generally corresponds to the configuration of the LNA integrated circuit 600 described with reference to FIGS. 6A and 6B. Particularly, the LNA integrated circuit 700 includes a first port 701a connected to a first switch 710a which forms a portion of a first receive signal path. The LNA integrated circuit 700 includes a second port 702a connected to a second switch 711a which forms a portion of a second receive signal path. As compared to FIGS. 6A and 6B, the LNA integrated circuit 700 includes a sixth port 703a connected to a third switch 712a which forms a portion of a third receive signal path. The LNA integrated circuit 700 includes a third port 720a connected to the first switch 710a, the second switch 711a, and the third switch 712a. The third port 720a is common to the first receive signal path, the second receive signal path, and the third receive signal path to allow routing signals through any of the receive signal paths based on the state of the switches 710a, 711a, and 712a through the third port 720a. The LNA integrated circuit 700 circuit further includes a fourth port 725a adjacent to the third port 720a. In certain implementations, the fourth port 725a and the third port 720a do not include any internal electrical connection between the third port 720a and the fourth port 725a (e.g., no connection internal to the LNA integrated circuit 700). Similar to the discussion with reference to FIGS. 6A and 6B, being adjacent indicates, at least in part, that the fourth port 725a is positioned relative to the third port 720a in a way to allow the third port 720a to be electrically connected to the fourth port 725a by some trace or conductive component applied external to the LNA integrated circuit 700.

The LNA integrated circuit 700 further includes a fifth port 750a adjacent to the fourth port 725a. The fifth port 750a is connected to the first LNA 760a. In some implementations the fifth port 750a may be internally electrically connected to the fourth port 725a (e.g., hard-wired as part of the original packaging process of the LNA integrated circuit 700). However, in other implementations, the fifth port 750a is not internally electrically connected to the fourth port 725a but may allow for an external connection to be applied between the fifth port 750a and another port such as the fourth port 725a. The LNA integrated circuit 700 further includes a first bypass path 730a that is connected to the fourth port 725a and that bypasses the LNA 760a.

Different configurations of receive signal paths may be provided by applying connections to the ports (e.g., different connection configurations between the third port 720a and the fourth port 725a) as described above with reference to FIGS. 6A and 6B.

The LNA integrated circuit 700 further includes a second LNA circuit portion 782b and a third LNA circuit portion 782c that are configured similarly with respect to the first LNA circuit portion 782a. As such, each of the second LNA circuit portion 782b and the third LNA circuit portion 782c have corresponding second and third LNAs 760b and 760c along with second and third bypass paths 730b and 730c along with input ports that may support the configurations as described with reference to FIGS. 6A and 6B.

In this way, in a configuration using the first LNA circuit portion 782a, a first receive signal path can be directly connected to the first LNA 760a by connecting the first receive signal path to the fourth port 725a while leaving the connection open between the third port 720a and the fourth port 725a. Thus, the first receive signal path does not experience the switch capacitances and additional resistance of the switches 710a, 711a, and 712a etc. In this same configuration, multiple receive signal paths may be connected to the second LNA 760b using the second LNA circuit portion 782b. For example second, third, and fourth receive signal paths (or only second and third) may be connected to the input ports 701b, 702b, and 703b. In addition, a connection is externally provided between the third port 720b and the fourth port 725b of the second LNA circuit portion 782b. In this way any of the second and third receive signal paths are able to be selectively connected to the second LNA 760b (or second bypass path 730b) to support multiple receive signal paths sharing the second LNA 760b. Likewise the third LNA circuit portion 782c could be configured either similarly to the first LNA circuit portion 782a or the second LNA circuit portion 782b or some other configuration of receive signal paths.

The output of each of the LNA circuit portions 782a, 782b, and 782c are connected to a switch matrix 770 (or other switching network) that is configured to output, at one or more output ports 780a, 780b, and 780c, a desired signal from either a corresponding LNA (LNAs 760a, 760b, and 760c) or bypass path (bypass paths 730a, 730b, and 730c).

FIG. 7B illustrates a configuration of the LNA integrated circuit 700 where a connection 727a is applied between the third port 720a and the fourth port 725a in the first LNA circuit portion 782a. The connection 727a is shown as a PCB trace as described above with reference to FIG. 6B but may be implemented in a number of manners to provide an electrical connection. As noted above, the connection 727a could be any type of electrical connection applied externally between the third port 720a and the fourth port 725a. Using the connection 727a may correspond to a configuration where multiple receive signal paths are connected to one or more of the first port 701a, the second port 702a, and the sixth port 703a of the first LNA circuit portion 782a. Likewise, each of the second LNA circuit portion 782b and the third LNA circuit portion 782c are configured similarly to the first LNA circuit portion 782a where connections 727b and 727c are applied between the corresponding third and fourth ports of the second and third LNA circuit portions 782b and 782c. As described above with reference to FIG. 7A, either of the second or third LNA circuit portions 782b and 782c may be configured differently than the first LNA circuit portion 782a (e.g., where the corresponding third and fourth ports are not connected).

In addition, FIG. 7B illustrates that corresponding inductors 740a, 740b, and 740c (or some matching network or isolation component) may be connected between the corresponding fourth and fifth ports 725a and 750a of each of the first, second, and third LNA circuit portions 782a, 782b, and 782c similarly as described above with respect the LNA integrated circuit 600 of FIGS. 6A and 6B.

In addition, FIG. 7B illustrates a switch 782c that is positioned in the bypass path. The switch 782c may be configured to selectively enable or disable the bypass path in certain implementations. While only shown in FIG. 7B a switch like the switch 782c may be included in any of the other bypass paths described herein.

FIG. 7C illustrates a configuration where there is no connection between the third port 720a and the fourth port 725a of the first LNA circuit portion 782a. The second and third LNA circuit portions 782b and 782c are similarly configured with no connection between their corresponding third and fourth ports. In this configuration, receive signal paths may be directly connected to the corresponding fourth ports 725a, 725b, and 725c of each of the LNA circuit portions 782a, 782b, and 782c. As compared to FIG. 7A, FIG. 7C illustrates that corresponding inductors 740a, 740b, and 740c (or some matching/isolation component) may be connected between the corresponding fourth and fifth ports 725a and 750a of each of the first, second, and third LNA circuit portions 782a, 782b, and 782c similarly as described above with respect the LNA integrated circuit 600 of FIGS. 6A and 6B. With respect to FIG. 7A, in some cases there may not be an inductor connected between the fourth port 725a and the fifth port 750a but instead either a direct external or internal connection may be provided between the fourth port 725a and the fifth port 750a. As described above with reference to FIG. 7A, either of the second or third LNA circuit portions 782b and 782c of FIG. 7C may be configured differently than the first LNA circuit portion 782a.

In one implementation, with respect to FIGS. 7A, 7B, and 7C, a first LNA circuit portion 782a has a different configuration than the second LNA circuit portion 782b. For example, the first LNA circuit portion 782a may not include a connection between the third port 720a and the fourth port 725a while the second LNA circuit portion 782b may include a connection 727b between the third port 720b and the fourth port 725b.

As described above, any of the ports described with reference to FIGS. 7A, 7B, and 7C may be configured as or include chip pads or bumps that allow for a respective connection external to the LNA integrated circuit 700 to be applied thereto.

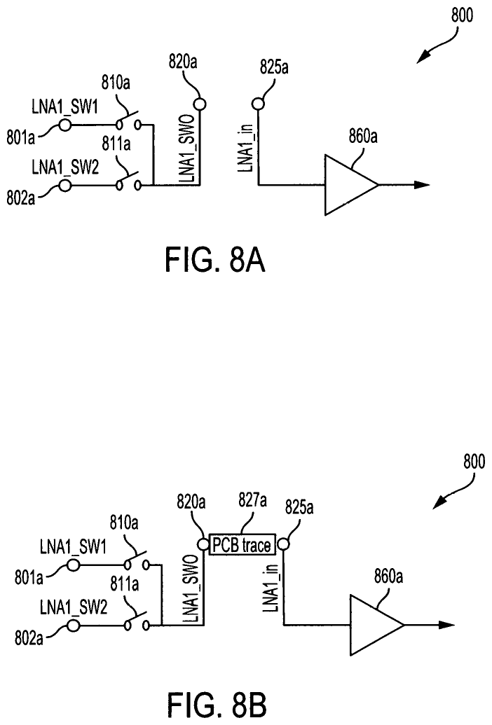

FIGS. 8A and 8B are schematic diagrams of another example of an LNA integrated circuit 800 capable of routing multiple receive signal paths to a single LNA. The LNA integrated circuit 800 is similar to that described with reference to FIGS. 6A and 6B but does not include a bypass path.

The LNA integrated circuit 800 includes a first port 801a connected to a first switch 810a which forms a portion of a first receive signal path. The LNA integrated circuit 800 includes a second port 802a connected to a second switch 811a which forms a portion of a second receive signal path. The LNA integrated circuit 800 includes a third port 820a connected to both the first switch 810a and the second switch 811a. The third port 820a is common to both the first receive signal path and the second receive signal path. The LNA integrated circuit 800 circuit further includes a fourth port 825a adjacent to the third port 820a. In certain implementations, the fourth port 825a and the third port 820a do not include any internal electrical connection between the third port 820a and the fourth port 825a (e.g., no connection internal to the LNA integrated circuit 800). In certain aspects, each of the third port 825a and fourth port 825a exposes a conductive component that is external to the LNA integrated circuit 800 to allow electrical connections to be applied to third port 825 and/or the fourth port 825a. The fourth port 825a is connected to the LNA 860a.

The LNA integrated circuit 800 may allow for connecting multiple receive signal paths to the LNA 860a in one configuration or be used for connecting a single receive signal path to the LNA 860a in another configuration. For example, in one configuration, the LNA integrated circuit 800 includes a connection 827a (FIG. 8B) between the third port 820a and the fourth port 825a. In an aspect, the connection 827a is external to the LNA integrated circuit 800. The connection 827a may be made using some form of conductive trace or other conductive connection between the third port 820a and the fourth port 825a.

In the configuration shown in FIG. 8B, the connection 827a between the third port 820a and the fourth port 825a allows for connecting the multiple receive signal paths to the LNA 860a. A first receive signal path may be connected to the first port 801a and a second receive signal path may be connected to the second port 802a. The first switch 810a and the second switch 811a allow for controlling which receive signal path (may be both) is connected to the LNA 860a. The implementation shown in FIG. 8B may therefore allow for integration into a device model that utilizes multiple receive signal paths that share the LNA 860a.

The switches described with reference to FIGS. 5-9 may each be controlled at a control terminal by respective control signals applied by a processor such as the data processor/controller 280 described with reference to FIG. 2 or any other controller that is configured to apply control signals to the LNA integrated circuits described herein. The one or more controllers may therefore be able to control a state of any the switches described herein according to a desired operating state/mode of the LNA integrated circuits described herein.

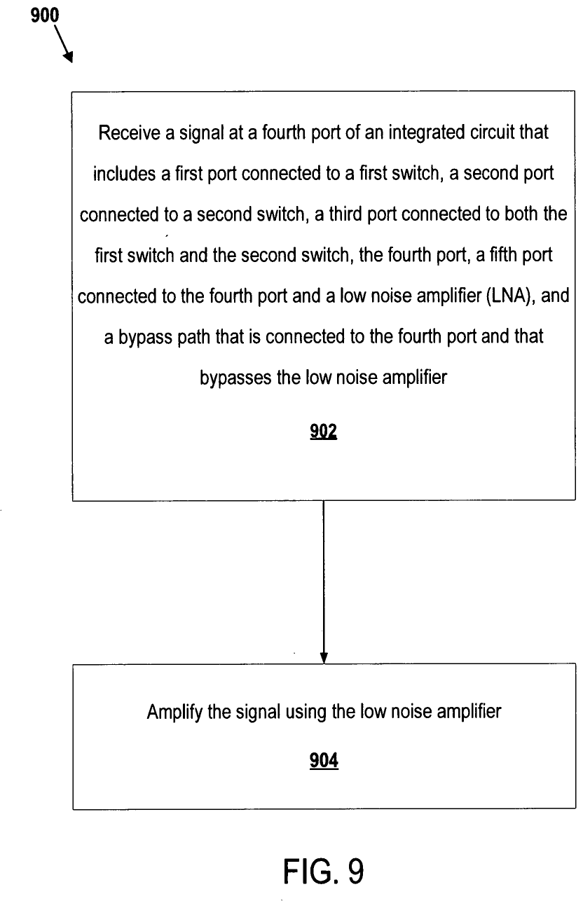

FIG. 9 is a flowchart of an example of a method 900 for amplifying a signal according to an aspect of the present disclosure. The method 900 is described with reference to FIGS. 6A and 6B, however the techniques described may be implemented using any of the previously described elements. Reference to elements is made by example only and is not intended to limit the ways in which the techniques can be implemented. The depicted sets of operations illustrate a few of the many ways in which the techniques may be implemented. As such, operations of a method may be repeated, combined, separated, omitted, performed in alternate orders, performed concurrently.

At block 902, the method 900 includes receiving a signal at a fourth port 625a of an integrated circuit 600 that includes a first port 601a connected to a first switch 610a, a second port 602a connected to a second switch 611a, a third port 620a connected to both the first switch 610a and the second switch 611a, the fourth port 625a, a fifth port 650a connected to the fourth port 625a and a low noise amplifier (LNA 660a), and a bypass path 630a that is connected to the fourth port 625a and that bypasses the low noise amplifier 660a.

At block 904, the method 900 further includes amplifying the signal using the low noise amplifier 660a.

The various operations of methods described above may be performed by any suitable means capable of performing the corresponding functions. The means may include various hardware and/or software component(s) and/or module(s), including, but not limited to a circuit, an application-specific integrated circuit (ASIC), or processor.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The various illustrative logical blocks, modules and circuits described in connection with the present disclosure may be implemented or performed with a general-purpose processor, a digital signal processor (DSP), an ASIC, a field programmable gate array (FPGA) or other programmable logic device (PLD), discrete gate or transistor logic, discrete hardware components, or any combination thereof designed to perform the functions described herein. A processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in hardware, an example hardware configuration may comprise a processing system in a wireless node. The processing system may be implemented with a bus architecture. The bus may include any number of interconnecting buses and bridges depending on the specific application of the processing system and the overall design constraints. The bus may link together various circuits including a processor, machine-readable media, and a bus interface. The bus interface may be used to connect a network adapter, among other things, to the processing system via the bus. The bus may also link various other circuits such as timing sources, peripherals, voltage regulators, power management circuits, and the like.

It is to be understood that the claims are not limited to the precise configuration and components illustrated above. Various modifications, changes and variations may be made in the arrangement, operation and details of the methods and apparatus described above without departing from the scope of the claims.

What is claimed is:

1. An apparatus comprising:
an integrated circuit comprising:
a first port connected to a first switch;
a second port connected to a second switch;
a third port connected to both the first switch and the second switch;
a fourth port;
a fifth port connected to a low noise amplifier (LNA); and
a bypass path that is connected to the fourth port and that bypasses the low noise amplifier.

2. The apparatus of claim 1, wherein the fourth port is adjacent to the third port.

3. The apparatus of claim 1, wherein the fourth port is configured to enable an external connection to be applied between the third port and the fourth port.

4. The apparatus of claim 1, wherein the fifth port is adjacent to the fourth port.

5. The apparatus of claim 1, wherein the LNA and the bypass path are connected to a switch matrix.

6. The apparatus of claim 1, further comprising a connection between the third port and the fourth port, the connection being external to the integrated circuit.

7. The apparatus of claim 6, wherein the connection comprises a printed circuit board (PCB) trace.

8. The apparatus of claim 6, wherein the connection comprises a multichip module (MCM) trace.

9. The apparatus of claim 6, further comprising an inductor connected between the fourth port and the fifth port.

10. The apparatus of claim 9, wherein the inductor is external to the integrated circuit.

11. The apparatus of claim 6, wherein a first receive signal path is connected to the first port and a second receive signal path is connected to the second port.

12. The apparatus of claim 1, wherein there is no connection between the third port and the fourth port.

13. The apparatus of claim 12, wherein a first receive signal path is connected to the fourth port.

14. The apparatus of claim 12, further comprising an inductor connected between the fourth port and the fifth port.

15. The apparatus of claim 14, wherein the inductor is external to the integrated circuit.

16. The apparatus of claim 1, further comprising an inductor connected between the fourth port and the fifth port.

17. The apparatus of claim 1, wherein at least one of the first port, the second port, the third port, the fourth port, and the fifth port comprises a chip pad.

18. The apparatus of claim 17, wherein at least one of the first port, the second port, the third port, the fourth port, and the fifth port comprises a flip chip bump.

19. The apparatus of claim 1, wherein each of the first port, the second port, the third port, the fourth port, and the fifth port comprises a chip pad.

20. The apparatus of claim 1, wherein the bypass path comprises a switch.

21. An apparatus comprising an integrated circuit, the integrated circuit comprising:
means for connecting a first port to a first switch;
means for connecting a second port to a second switch;
means for connecting a third port to both the first switch and the second switch;
means for connecting a fourth port to a bypass path, wherein the bypass path bypasses a low noise amplifier (LNA); and
means for connecting a fifth port to the LNA.

22. The apparatus of claim 21, further comprising means for connecting the third port to the fourth port, wherein the means for connecting is external to the integrated circuit.

23. The apparatus of claim 21 comprising a means to connect a first receive signal path to the fourth port.

24. The apparatus of claim 23, wherein the first receive signal path is isolated from the first switch and the second switch.

25. A method of amplifying a signal, the method comprising:
receiving the signal at a fourth port of an integrated circuit that includes a first port connected to a first switch, a second port connected to a second switch, a third port connected to both the first switch and the second switch, the fourth port, a fifth port connected to the fourth port and a low noise amplifier (LNA), and a bypass path that is connected to the fourth port and that bypasses the low noise amplifier; and
amplifying the signal using the low noise amplifier.

26. The method of claim 25, wherein there is an inductor connected between the fourth port and the fifth port.

27. The method of claim 25, wherein there is no connection between the third port and the fourth port.

28. The method of claim 25, wherein at least one of the first port, the second port, the third port, the fourth port, and the fifth port comprises a chip pad.
